(19) United States
(12) Patent Application Publication
(10) Pub. No.: US 2024/0141492 A1
(43) Pub. Date: May 2, 2024

(54) SEMICONDUCTOR MANUFACTURING SUSCEPTOR POCKET EDGE FOR PROCESS IMPROVEMENT

(71) Applicant: Applied Materials, Inc., Santa Clara, CA (US)

(72) Inventors: Prasanth Narayanan, Santa Clara, CA (US); Vijayabhaskara Venkatagiriyappa, Bangalore (IN); Keiichi Tanaka, San Jose, CA (US); Ning Li, San Jose, CA (US); Robert B. Moore, Bigfork, MT (US); Robert C. Linke, Mountain View, CA (US); Mandyam Sriram, San Jose, CA (US); Mario D. Silvetti, Fountain Hills, AZ (US); Michael Racine, Phoenix, AZ (US); Tae Kwang Lee, Pleasanton, CA (US)

(73) Assignee: Applied Materials, Inc., Santa Clara, CA (US)

(21) Appl. No.: 18/125,215

(22) Filed: Mar. 23, 2023

(30) Foreign Application Priority Data
Oct. 27, 2022 (IN) 202241061142

(51) Int. Cl. C23C 16/458

(52) U.S. Cl. CPC C23C 16/4581; C23C 16/4583

(57) ABSTRACT

Susceptor assemblies having a susceptor base with a plurality of pockets formed in a surface thereof are described. Each of the pockets has a pocket edge angle in the range of 30 to 75° and a pocket edge radius in the range of 0.40±0.05 mm to 1.20 mm±0.05 mm. The pockets have a raised central region and an outer region that is deeper than the raised central region, relative to the surface of the surface of the susceptor base.

### CROSS-REFERENCE TO RELATED APPLICATIONS

This application claims priority to India application for patent numbered 202241061142, dated Oct. 27, 2022, the entire disclosure of which is hereby incorporated by reference herein.

### TECHNICAL FIELD

Embodiments of the disclosure relate to substrate supports for process chambers. In particular, embodiments of the disclosure are directed to susceptors with wafer pockets configured to prevent wafer breakage.

### BACKGROUND

In some CVD and ALD processing chambers, the substrates, also referred to herein as wafers, move relative to the precursor injector and heater assembly. If the motion creates acceleration forces larger than that of the frictional force, the wafer can become displaced causing damage or related issues. The wafers placed off-axis can slip at high acceleration/deceleration on a moving/rotating susceptor. Friction from the weight of the wafer itself is insufficient to hold the wafer on tools where higher throughput is desired.

To prevent the rotation forces from dislodging the wafer during process, additional hardware to clamp or chuck the wafer in place may be needed. The additional hardware can be expensive, difficult to install, difficult to use and/or cause damage to the wafers during use.

In many batch processing chambers, multiple substrates are supported on large platen susceptors for processing. The susceptors typically rotate around a central shaft at constant or varying speeds. Without support, the substrates on the susceptor would move outward toward the edge of the susceptor as a result of centrifugal force. One method of preventing substrates from moving on the susceptor includes a pocket formed in the top of the susceptor sized for hold the substrate.

Current pocket design can cause stress on the coating on the pocket edge resulting in edge cracking. Higher stress causes cracking or other defects of the pocket edge which leads to particle issues on the edge of the wafer and on-wafer performance.

Accordingly, there is a need in the art for improved apparatus to prevent pocket edge cracking due to high stress with film accumulation.

### SUMMARY

One or more embodiments of the disclosure are directed to susceptor assemblies comprising a susceptor base having a plurality of pockets formed in a surface thereof. Each of the pockets has a pocket edge angle in the range of 30 to 75° and a pocket edge radius in the range of 0.40 mm to 1.20 mm±0.05 mm.

A susceptor assembly comprising a susceptor base having a plurality of pockets formed in a surface thereof. Each of the pockets comprises a raised central region defining a wafer placement surface and an outer portion that is deeper than the raised central region, relative to the surface of the susceptor base. The wafer placement surface is in the range of 0.1 mm to 0.4 mm higher than a surface of the outer portion of the pocket. Each of the pockets has a pocket edge angle in the range of 30 to 75° and a pocket edge radius in the range of 0.40±0.05 mm to 1.20 mm±0.05 mm.

A susceptor assembly comprising a susceptor base having a plurality of pockets formed in a surface thereof. Each of the pockets comprises a raised central region defining a wafer placement surface and an outer portion that is deeper than the raised central region, relative to the surface of the susceptor base. The raised central region has a plurality of raised mesas with gas channels allowing a flow of backside gas from a center portion of the raised central region to the outer portion of the pocket. The wafer placement surface is in the range of 0.1 mm to 0.4 mm higher than a surface of the outer portion of the pocket. Each of the pockets has a pocket edge angle in the range of 30 to 75° and a pocket edge radius in the range of 0.40±0.05 mm to 1.20 mm±0.05 mm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments of this disclosure and are therefore not to be considered limiting of its scope, for the disclosure may admit to other equally effective embodiments.

FIG. 1 shows a cross-sectional view of a batch processing chamber in accordance with one or more embodiment of the disclosure;

FIG. 2 shows a partial orthographic view of a batch processing chamber in accordance with one or more embodiment of the disclosure;

FIG. 3 shows a schematic view of a batch processing chamber in accordance with one or more embodiment of the disclosure;

FIG. 4 shows a schematic view of a portion of a wedge-shaped gas distribution assembly for use in a batch processing chamber in accordance with one or more embodiment of the disclosure;

FIG. 5 shows a schematic view of a batch processing chamber in accordance with one or more embodiment of the disclosure;

FIG. 6 shows a portion of a cross-section of a susceptor pocket in accordance with one or more embodiment of the disclosure;

FIG. 7 shows a portion of a cross-section of a susceptor assembly in accordance with one or more embodiments of the disclosure

FIG. 8 shows a perspective view of a pocket in a susceptor in accordance with one or more embodiment of the disclosure;

FIG. 9 shows an orthographic view of a susceptor assembly in accordance with one or more embodiments of the disclosure;

FIG. 10 shows a partial cross-sectional schematic view of a susceptor according to one or more embodiment of the disclosure;

FIG. 11 shows a portion of a pocket in a susceptor with a wafer positioned therein in accordance with one or more embodiment of the disclosure; and

FIG. 12 shows a partial cross-sectional view of a susceptor with a pocket and wafer positioned therein according to an embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate, or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface. The terms “wafer”, “workpiece”, and the like, are used interchangeably with substrate.

As used in this specification and the appended claims, the terms “precursor”, “reactant”, “reactive gas” and the like are used interchangeably to refer to any gaseous species that can react with the substrate surface.

In some spatial ALD chambers, the precursors used for deposition are injected in close proximity to the wafer surface. To develop the desired gas dynamics, the injector channels are independently controlled at a higher pressure than the surrounding chamber. By creating a pressure differential between the front side of the wafer and the back side of the wafer, a positive pressure force adequate to hold the wafer against relativity larger acceleration force can be generated.

Embodiments of the disclosure are directed to the use of differential pressure to hold substrates (wafers) on a susceptor under large acceleration forces. The large acceleration forces occur as a result of high rotation speeds, which may be experienced in carousel-type processing chambers, from larger batch sizes and processing speeds or higher reciprocating motion for higher wafer throughput.

In some embodiments, the wafers sit in shallow pockets on a susceptor below the injector assemblies. The susceptor can provide heat transfer, improved gas dynamics and act as a carrier vehicle for the substrates.

Embodiments of the disclosure are directed to susceptors with an angled hole for vacuum from inner diameter of susceptor-bottom up to the wafer pocket. The susceptor can get a vacuum source through the rotation shaft and rotation motor below the shaft. If the susceptor is made of Silicon Carbide Coated (SiC) Graphite, then additional holes which are spaced, for example, every three times hole diameter, are needed from top or bottom of the susceptor for better penetration of the SiC coating. The redundant holes are plugged for vacuum. Graphite plugs can be press-fit before SiC Coating and then the susceptor is SiC coated. In some embodiments, threaded SiC Coated plugs on SiC Coated susceptor and a second SiC coat can be applied for better sealing of graphite with SiC for more corrosive applications.

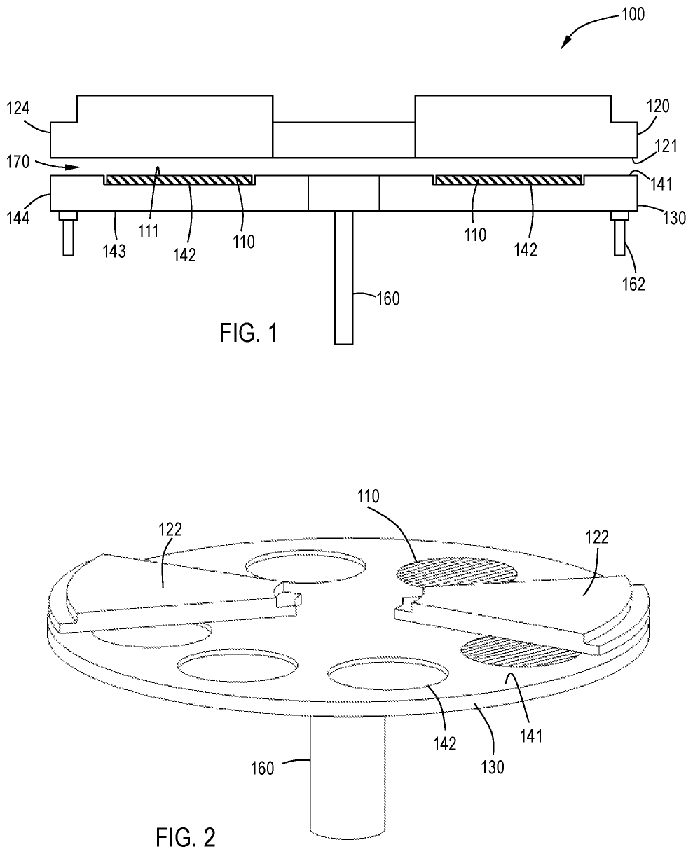

FIG. 1 shows a cross-section of a processing chamber 100 including a gas distribution assembly 120, also referred to as injectors or an injector assembly, and a susceptor assembly 140. The gas distribution assembly 120 is any type of gas delivery device used in a processing chamber. The gas distribution assembly 120 includes a front surface 121 which faces the susceptor assembly 140. The front surface 121 can have any number or variety of openings to deliver a flow of gases toward the susceptor assembly 140. The gas distribution assembly 120 also includes an outer peripheral edge 124 which in the embodiments shown, is substantially round.

The specific type of gas distribution assembly 120 used can vary depending on the particular process being used. Embodiments of the disclosure can be used with any type of processing system where the gap between the susceptor and the gas distribution assembly is controlled. While various types of gas distribution assemblies can be employed (e.g., showerheads), embodiments of the disclosure may be particularly useful with spatial gas distribution assemblies which have a plurality of substantially parallel gas channels. As used in this specification and the appended claims, the term “substantially parallel” means that the elongate axis of the gas channels extend in the same general direction. There can be slight imperfections in the parallelism of the gas channels. In a binary reaction, the plurality of substantially parallel gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the process region through the purge gas P channel(s). A substrate moving from one end of the gas distribution assembly to the other end will be exposed to each of the process gases in turn, forming a layer on the substrate surface.

In some embodiments, the gas distribution assembly 120 is a rigid stationary body made of a single injector unit. In one or more embodiments, the gas distribution assembly 120 is made up of a plurality of individual sectors (e.g., injector units 122), as shown in FIG. 2. Either a single piece body or a multi-sector body can be used with the various embodiments of the disclosure described.

A susceptor assembly 140 is positioned beneath the gas distribution assembly 120. A susceptor assembly 140, as used herein, refers to a combination of components including a susceptor 130 and a support post 160. Other components can be included in a susceptor assembly 140 without deviating from the scope of the disclosure.

The susceptor assembly 140 includes a susceptor 130 with a top surface 141 and at least one pocket 142 in the top surface 141. The susceptor 130 also has a bottom surface 143 and an edge 144. As used herein, the top surface 141, the pocket 142, bottom surface 143 and edge 144 refer to both the susceptor 130 and the susceptor assembly 140, unless otherwise indicated.

The pocket 142 can be any suitable shape and size depending on the shape and size of the wafers 110 being processed. In the embodiment shown in FIG. 1, the at least one pocket 142 (also referred to as a recess) has a flat bottom to support the bottom (back surface 113) of the wafer 110; however, the bottom of the recess can vary. In some embodiments, the pocket 142 has steps 134 or step regions around the outer peripheral edge 146 of the pocket 142. The steps 134 are sized to support the outer peripheral edge 115 of the wafer 110. The amount of the outer peripheral edge 115 of the wafer that is supported by the steps 134 can vary depending on, for example, the thickness of the wafer and the presence of features already present on the back side of the wafer (e.g., semiconductor or electronic devices formed thereon).

In some embodiments, as shown in FIG. 1, the pocket 142 in the top surface 141 of the susceptor 130 (or susceptor assembly 140) is sized so that a wafer 110 supported in the pocket 142 has a top surface 111 substantially coplanar with the top surface 141 of the susceptor 130. As used in this specification and the appended claims, the term “substantially coplanar” means that the top surface of the wafer and the top surface of the susceptor assembly are coplanar within ±0.2 mm. In some embodiments, the top surfaces are coplanar within 0.5 mm, ±0.4 mm, ±0.35 mm, ±0.30 mm, ±0.25 mm, ±0.20 mm, ±0.15 mm, ±0.10 mm or ±0.05 mm.

The susceptor assembly 140 of FIG. 1 includes a support post 160 which is capable of lifting, lowering and rotating the susceptor 130. The susceptor assembly 140 may include a heater, or gas lines, or electrical components within the center of the support post 160. The support post 160 may be the primary means of increasing or decreasing the gap 170 between the top surface 141 of the susceptor 130 (or susceptor assembly 140) and the front surface 121 of the gas distribution assembly 120, moving the susceptor assembly 140 into proper position for processing. The susceptor assembly 140 may also include fine tuning actuators 162 which can make micro-adjustments to the susceptor assembly 140 to create a predetermined gap 170 between the susceptor assembly 140 and the gas distribution assembly 120.

In some embodiments, the gap 170 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The processing chamber 100 shown in the Figures is a carousel-type chamber in which the susceptor assembly 140 can hold a plurality of wafers 110. As shown in FIG. 2, the gas distribution assembly 120 may include a plurality of separate injector units 122, each injector unit 122 being capable of depositing a film on the wafer, as the wafer is moved beneath the injector unit. Two pie-shaped injector units 122 are shown positioned on approximately opposite sides of and above the susceptor assembly 140. This number of injector units 122 is shown for illustrative purposes only. It will be understood that more or less injector units 122 can be included. In some embodiments, there are a sufficient number of pie-shaped injector units 122 to form a shape conforming to the shape of the susceptor assembly 140. In some embodiments, each of the individual pie-shaped injector units 122 may be independently moved, removed and/or replaced without affecting any of the other injector units 122. For example, one segment may be raised to permit a robot to access the region between the susceptor assembly 140 and gas distribution assembly 120 to load/unload wafers 110.

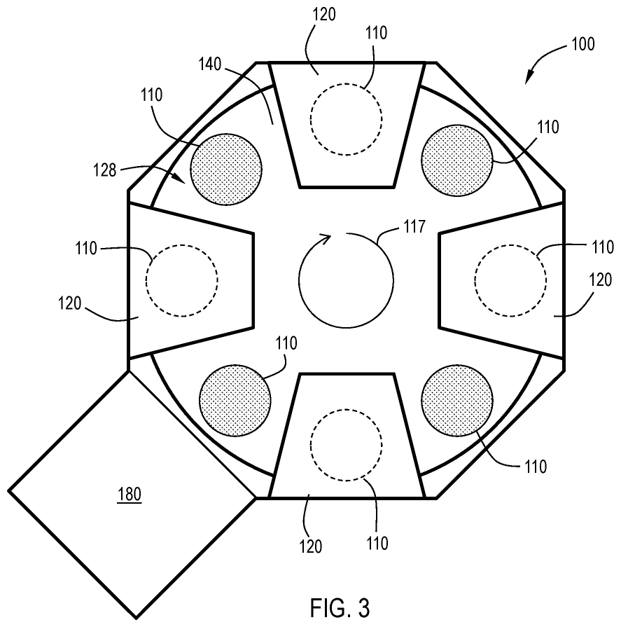

Processing chambers having multiple gas injectors can be used to process multiple wafers simultaneously so that the wafers experience the same process flow. For example, as shown in FIG. 3, the processing chamber 100 has four gas injector assemblies and four wafers 110. At the outset of processing, the wafers 110 can be positioned between the gas distribution assemblies 120. Rotating 117 the susceptor assembly 140 by 45° will result in each wafer 110 which is between gas distribution assemblies 120 to be moved to a gas distribution assembly 120 for film deposition, as illustrated by the dotted circle under the gas distribution assemblies 120. An additional 45° rotation would move the wafers 110 away from the gas distribution assemblies 120. The number of wafers 110 and gas distribution assemblies 120 can be the same or different. In some embodiments, there are the same numbers of wafers being processed as there are gas distribution assemblies. In one or more embodiments, the number of wafers being processed are fraction of or an integer multiple of the number of gas distribution assemblies. For example, if there are four gas distribution assemblies, there are 4× wafers being processed, where x is an integer value greater than or equal to one. In an exemplary embodiment, the gas distribution assembly 120 includes eight process regions separated by gas curtains and the susceptor assembly 140 can hold six wafers.

The processing chamber 100 shown in FIG. 3 is merely representative of one possible configuration and should not be taken as limiting the scope of the disclosure. Here, the processing chamber 100 includes a plurality of gas distribution assemblies 120. In the embodiment shown, there are four gas distribution assemblies (also called gas distribution assemblies 120) evenly spaced about the processing chamber 100. The processing chamber 100 shown is octagonal; however, those skilled in the art will understand that this is one possible shape and should not be taken as limiting the scope of the disclosure. The gas distribution assemblies 120 shown are trapezoidal, but can be a single circular component or made up of a plurality of pie-shaped segments, like that shown in FIG. 2.

The embodiment shown in FIG. 3 includes a load lock chamber 180, or an auxiliary chamber like a buffer station. This chamber 180 is connected to a side of the processing chamber 100 to allow, for example the substrates (also referred to as wafers 110) to be loaded/unloaded from the processing chamber 100. A wafer robot may be positioned in the chamber 180 to move the substrate onto the susceptor.

Rotation of the carousel (e.g., the susceptor assembly 140) can be continuous or intermittent (discontinuous). In continuous processing, the wafers are constantly rotating so that they are exposed to each of the injectors in turn. In discontinuous processing, the wafers can be moved to the injector region and stopped, and then to the region 128 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing steps between each layer deposition (e.g., exposure to plasma).

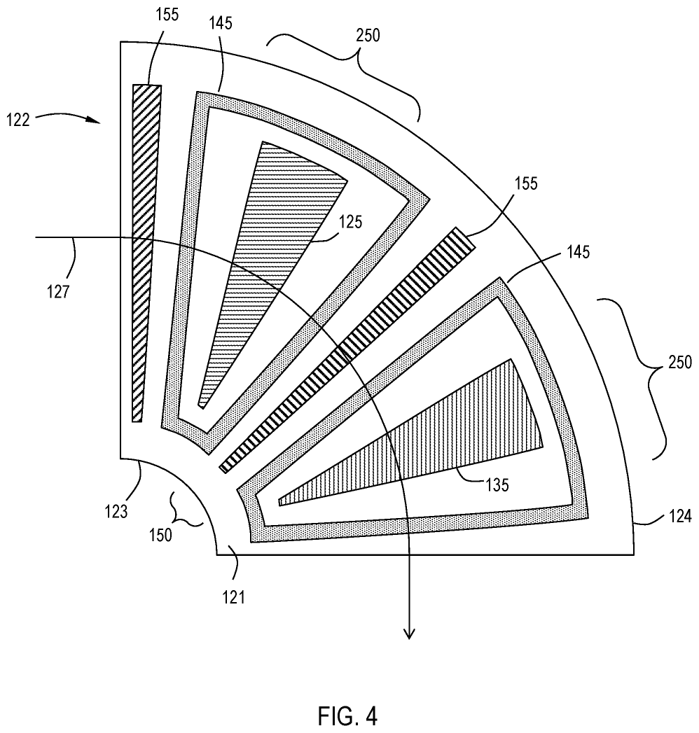

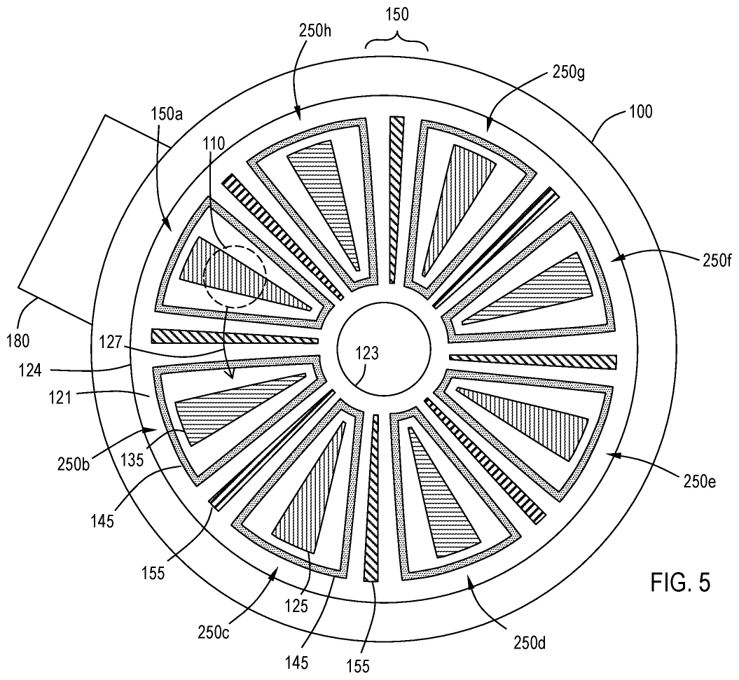

FIG. 4 shows a sector or portion of a gas distribution assembly 120, which may be referred to as an injector unit 122. The injector units 122 can be used individually or in combination with other injector units. For example, as shown in FIG. 5, four of the injector units 122 of FIG. 4 are combined to form a single gas distribution assembly 120. (The lines separating the four injector units are not shown for clarity.) While the injector unit 122 of FIG. 4 has both a first reactive gas port 125 and a second gas port 135 in addition to purge gas ports 155 and vacuum ports 145, an injector unit 122 does not need all of these components.

Referring to both FIGS. 4 and 5, a gas distribution assembly 120 in accordance with one or more embodiment may comprise a plurality of sectors (or injector units 122) with each sector being identical or different. The gas distribution assembly 120 is positioned within the processing chamber and comprises a plurality of elongate gas ports 125, 135, 155 and vacuum ports 145 in a front surface 121 of the gas distribution assembly 120. The plurality of elongate gas ports 125, 135, 155 and vacuum ports 145 extend from an area adjacent the inner peripheral edge 123 toward an area adjacent the outer peripheral edge 124 of the gas distribution assembly 120. The plurality of gas ports shown include a first reactive gas port 125, a second gas port 135, a vacuum port 145 which surrounds each of the first reactive gas ports and the second reactive gas ports and a purge gas port 155.

With reference to the embodiments shown in FIG. 4 or 5, when stating that the ports extend from at least about an inner peripheral region to at least about an outer peripheral region, however, the ports can extend more than just radially from inner to outer regions. The ports can extend tangentially as vacuum port 145 surrounds reactive gas port 125 and reactive gas port 135. In the embodiment shown in FIGS. 4 and 5, the wedge-shaped reactive gas ports 125, 135 are surrounded on all edges, including adjacent the inner peripheral region and outer peripheral region, by a vacuum port 145.

Referring to FIG. 4, as a substrate moves along path 127, each portion of the substrate surface is exposed to the various reactive gases. To follow the path 127, the substrate will be exposed to, or “see”, a purge gas port 155, a vacuum port 145, a first reactive gas port 125, a vacuum port 145, a purge gas port 155, a vacuum port 145, a second gas port 135 and a vacuum port 145. Thus, at the end of path 127 shown in FIG. 4, the substrate has been exposed to the first reactive gas from a first reactive gas port 125 and the second reactive gas from the second reactive gas port 135 to form a layer. The injector unit 122 shown makes a quarter circle but could be larger or smaller. The gas distribution assembly 120 shown in FIG. 5 can be considered a combination of four of the injector units 122 of FIG. 4 connected in series.

The injector unit 122 of FIG. 4 shows a gas curtain 150 that separates the reactive gases. The term “gas curtain” is used to describe any combination of gas flows or vacuum that separates reactive gases from mixing. The gas curtain 150 shown in FIG. 4 comprises the portion of the vacuum port 145 next to the first reactive gas port 125, the purge gas port 155 in the middle and a portion of the vacuum port 145 next to the second gas port 135. This combination of gas flow and vacuum can be used to prevent or minimize gas phase reactions of the first reactive gas and the second reactive gas.

Referring to FIG. 5, the combination of gas flows and vacuum from the gas distribution assembly 120 form a separation into a plurality of process regions 250. The process regions are roughly defined around the individual gas ports 125, 135 with the gas curtain 150 between 250. The embodiment shown in FIG. 5 makes up eight separate process regions 250 with eight separate gas curtains 150 between. A processing chamber can have at least two process regions. In some embodiments, there are at least three, four, five, six, seven, eight, nine, 10, 11 or 12 process regions.

During processing a substrate may be exposed to more than one process region 250 at any given time. However, the portions that are exposed to the different process regions will have a gas curtain separating the two. For example, if the leading edge of a substrate enters a process region including the second gas port 135, a middle portion of the substrate will be under a gas curtain 150 and the trailing edge of the substrate will be in a process region including the first reactive gas port 125.

A factory interface 280, which can be, for example, a load lock chamber, is shown connected to the processing chamber 100. A wafer 110 is shown superimposed over the gas distribution assembly 120 to provide a frame of reference. The wafer 110 may often sit on a susceptor assembly to be held near the front surface 121 of the gas distribution assembly 120. The wafer 110 is loaded via the factory interface 280 into the processing chamber 100 onto a substrate support or susceptor assembly (see FIG. 3). The wafer 110 can be shown positioned within a process region because the substrate is located adjacent the first reactive gas port 125 and between two gas curtains 150. Rotating the wafer 110 along path 127 will move the substrate counter-clockwise around the processing chamber 100. Thus, the wafer 110 will be exposed to the first process region 250a through the eighth process region 250h, including all process regions between.

Embodiments of the disclosure are directed to processing methods comprising a processing chamber 100 with a plurality of process regions 250a-250h with each process region separated from an adjacent region by a gas curtain 150. For example, the processing chamber shown in FIG. 5. The number of gas curtains and process regions within the processing chamber can be any suitable number depending on the arrangement of gas flows. The embodiment shown in FIG. 5 has eight gas curtains 150 and eight process regions 250a-250h.

A plurality of wafers 110 are positioned on a substrate support, for example, the susceptor assembly 140 shown FIGS. 1 and 2. The plurality of wafers 110 are rotated around the process regions for processing. Generally, the gas curtains 150 are engaged (gas flowing and vacuum on) throughout processing including periods when no reactive gas is flowing into the chamber.

One or more embodiments of the disclosure provide susceptor pockets with modified/enhanced susceptor pocket edge design using pocket edge radius and edge angles to improve pocket edge performance. Embodiments of the disclosure address the issue of pocket edge cracking due to stress with accumulation on the susceptor.

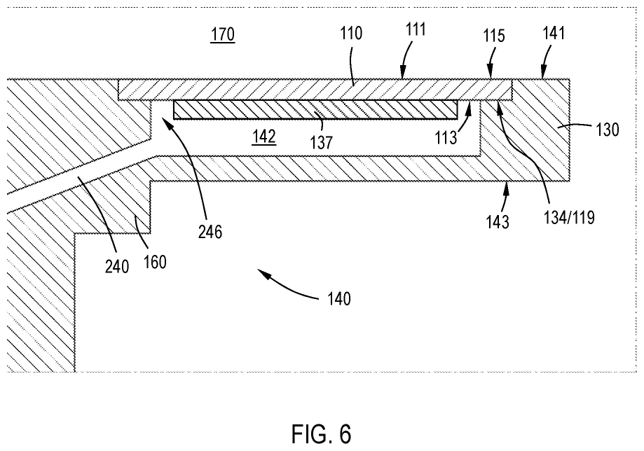

FIG. 6 shows a cross-sectional view of a susceptor assembly 140 configured to help prevent deflection of the wafer 110 by providing a greater support surface area for the back surface 113 of the wafer 110. Here, the wafer 110 is supported across a majority of the back surface 113 by the susceptor 130. The center portion 137 of the pocket 142 of the susceptor 130 is not free floating, but is connected to the remainder of the susceptor 130 in a different plane than the cross-sectional view shows.

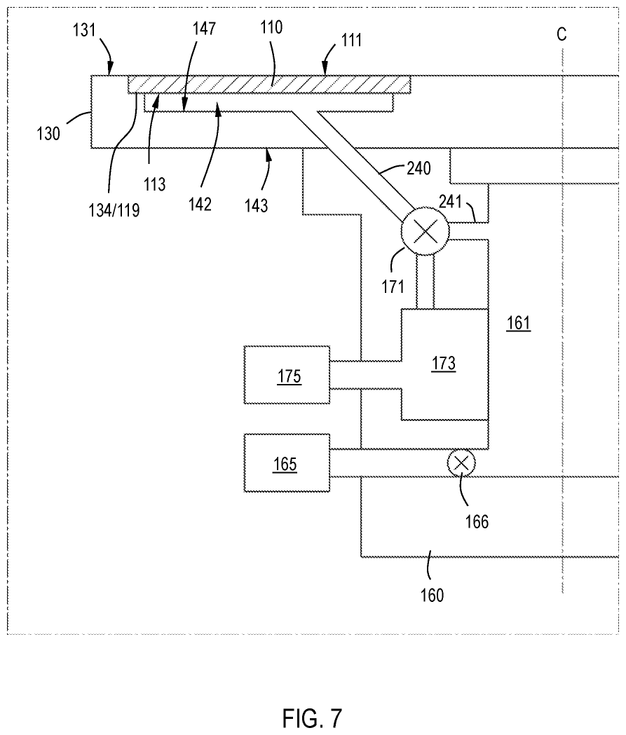

A passage 240 extends between the drive shaft (support post 160) of the susceptor assembly 140, or from a hollow area 161 (see FIG. 7) within the drive shaft (support post 160) toward the pocket 142. The passage 240 connects to a channel 246 which extends toward the top surface 141 of the susceptor 130. A vacuum within hollow area 161 chucks the wafer 110 to the susceptor 130 through channel 246 and passage 240.

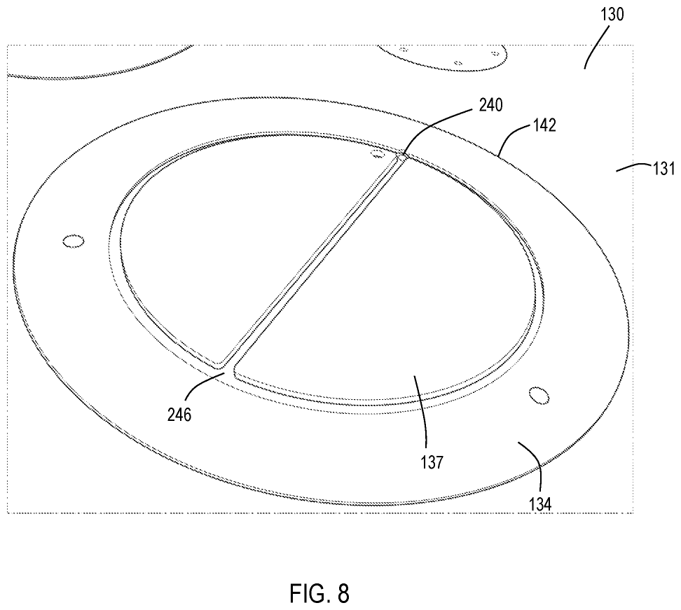

FIG. 8 shows a orthographic view of a susceptor 130 similar to that of FIG. 6. The susceptor 130 shown has a pocket 142 with a relatively large step 134 to support the outer peripheral edge 119 of the wafer (see FIG. 6). The pocket 142 includes a passage 240 that connects to channel 246 to a vacuum in the drive shaft (support post 160). The channel 246 illustrated in FIG. 8 is shaped like a capital Greek letter theta, providing a channel ring with a channel portion extending across the diameter of the ring. The center portion 137 of the susceptor 130 is about coplanar with the step 134 so that the center portion 137 and the step 134 support the wafer at the same time.

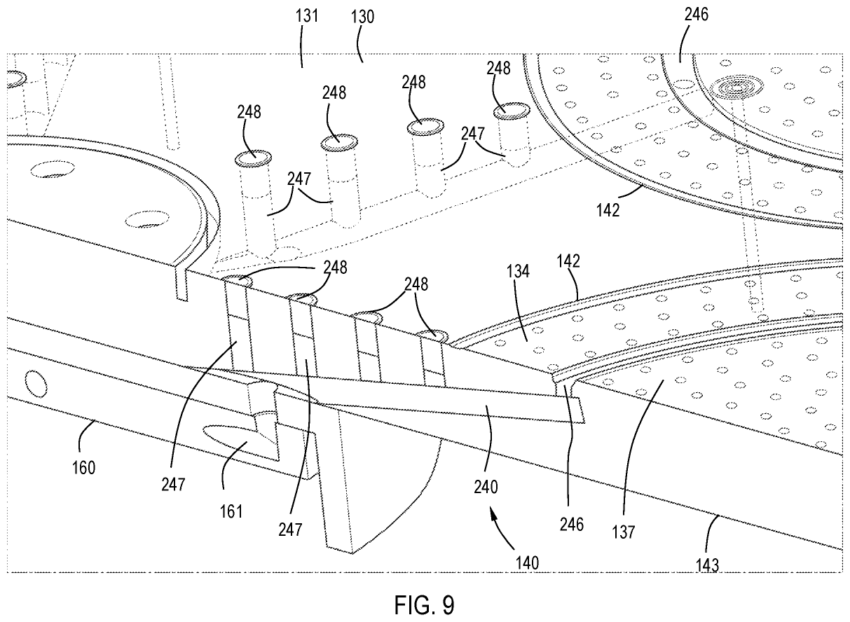

FIG. 9 shows a orthographic view of a susceptor assembly 140 in accordance with one or more embodiments of the disclosure. Here the passage 240 extends from drive shaft (support post 160) toward the pocket 142 connecting the hollow area 161, which acts as a vacuum plenum, with the channel 246 in the pocket 142.

The passage 240 illustrated has a plurality of holes 247 connecting the top surface 141 of the susceptor 130 with the passage 240. In some embodiments, there is at least one hole extending from one of the top surface 141 of the susceptor 130 or the bottom surface 143 of the susceptor 130 to the passage 240.

The holes 247 can be created (e.g., drilled) during the manufacture of the susceptor 130 to allow the inside of the passage 240, or portions of the inside of the passage 240, to be coated and/or sealed. For example, in some embodiments, the susceptor 130 has a silicon carbide coating. The susceptor 130 of some embodiments is a silicon carbide coated graphite. The holes 247 allow the silicon carbide to be coated on the passage 240 and are then sealed with plugs 248. The plugs 248 can be made of any suitable material including, but not limited to, silicon carbide, silicon carbide coated graphite, a material with a silicon carbide coating and/or graphite. After the plugs 248 have been inserted into the holes 247, the susceptor 130 can be coated with silicon carbide again to provide an additional sealing of the holes 247. The plugs 248 can be press-fit (e.g., friction fit), connected to the holes 247 by complementary screw threads or connected by some other mechanical connection (e.g., epoxy or brazing).

During the preparation of a silicon carbide coated susceptor 130, the holes 247 provide a useful passageway for the silicon carbide to coat the passage 240. The size and spacing of the holes 247 may have an impact on the efficiency of the coating. In some embodiments, the holes 247 are spaced in increments of the hole diameter. For example, if the holes are 5 mm in diameter, the spacing might be 5x mm, with x being any suitable value. For example, the spacing may be 1, 2, 3, 4, 5, 6, 7, 8, 9 or 10 times the hole diameter. The holes 247 can be positioned at any suitable points along the length of the passage 240, and do not need to be evenly distributed across the passage 240 length. As shown in FIG. 9, the holes 247 are concentrated toward the inner portion of the susceptor 130, where the passage 240 is furthest from the top surface 141 of the susceptor 130.

The passages 240 can be used to supply a vacuum to the pocket 142 to chuck the wafer 110. However, when the wafer 110 is processed, the vacuum may be too strong to easily remove the processed wafer from the recess. To ease removal of the wafer, the passages 240 can also be used to provide a flow of gas toward the back surface 113 of the wafer 110. Thus providing a positive pressure to the back side of the wafer 110 to allow the wafer 110 to be easily removed from the susceptor 130.

Referring back to FIG. 7, a schematic cross-sectional view of a susceptor assembly in accordance with one or more embodiments of the disclosure is provided. Here, the pocket 142 is connected to the passage 240 which leads to the hollow area 161 within the drive shaft. A valve 171 is positioned within the passage 240. The valve 171 can allow a fluid connection between the passage 240 and the hollow area 161 through connector 241. If a vacuum, or region of decreased pressure, is formed in the hollow area 161, then the valve 171 can connect the hollow area 161 to the pocket 142 through the connector 241 and passage 240. The valve 171 can be switched to break the fluid connection between the passage 240 and the hollow area 161.

The valve 171 can be set to a closed position, isolating the passage 240, or to a position where a connection is formed between the passage 240 to a dechucking gas plenum 173 through connector 242. The dechucking gas plenum 173 is shown in fluid communication with a dechucking gas source 175. The dechucking gas source 175 can comprise any suitable gas including, but not limited to, nitrogen, argon, helium or an inert gas.

The vacuum source 165 can be connected to the hollow area 161 through valve 166. The valve 166 can be used to isolate the hollow area 161 from the vacuum source 165 in the event that there is a loss of vacuum from the vacuum source 165. This allows the hollow area 161 to act as a vacuum plenum so that the wafers on the susceptor assembly remain chucked while the vacuum source is being reconnected or repaired.

Each of the individual pocket 142 in the susceptor 130 can include a separate passage 240 and valve 171. This allows each individual pocket 142 to be isolated from the vacuum in the hollow area 161. For example, a processed wafer 110 can be moved to the loading/unloading area of the processing chamber. The valve 171 can be closed or switched to the dechucking gas plenum 173 to cause a positive pressure on the back side of the wafer 110, allowing a robot to pick up the wafer. After picking up the wafer, the valve 171 can close so that the pressure in the pocket 142 will be equal to the pressure of the chamber. A new wafer 110 can be placed in the pocket 142 and the valve 171 switched back to allow fluid connection with the hollow area 161 to chuck the new wafer 110.

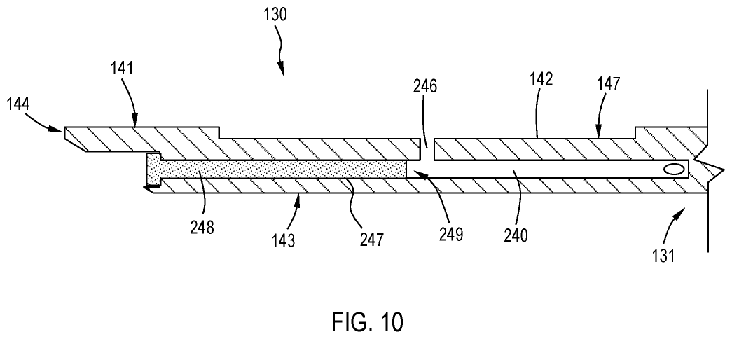

FIG. 10 shows another embodiment of a susceptor 130. The susceptor 130 has a top surface 141 and bottom surface 143 defining a thickness of the susceptor 130. At least one pocket 142 is formed in the top surface 141 of the susceptor 130 and is sized to support a wafer (not shown) during processing. A passage 240 connects the pocket 142 to a vacuum source (not shown) through channel 246.

The passage 240 is formed in the susceptor 130 by drilling from the edge 144 of the susceptor 130 toward the center 131 of the susceptor 130. The channel 246 is formed to connect the bottom 147 of the pocket 142 to the passage 240. In the illustrated embodiment, the channel 246 is formed in approximately the center of the pocket 142. However, the skilled artisan will recognize that this is merely one possible configuration and should not be taken as limiting the scope of the disclosure.

To prevent leakage, the passage 240 is sealed using plug 248 which is inserted into the end of the passage 240 adjacent the edge 144 of the susceptor 130. The plug 248 of some embodiments is screwed into position in passage 240, allowing the plug 248 to be removed for replacement of cleaning of the passage 240. In some embodiments, the plug 248 is permanently affixed into position in the passage 240. In the embodiment illustrated, the plug 248 does not extend completely to the channel 246 leaving a dead leg 249 in the passage 240. As the passage 240 is primarily used for vacuum chucking, the presence of the dead leg 249 does not interfere with use of the susceptor 130.

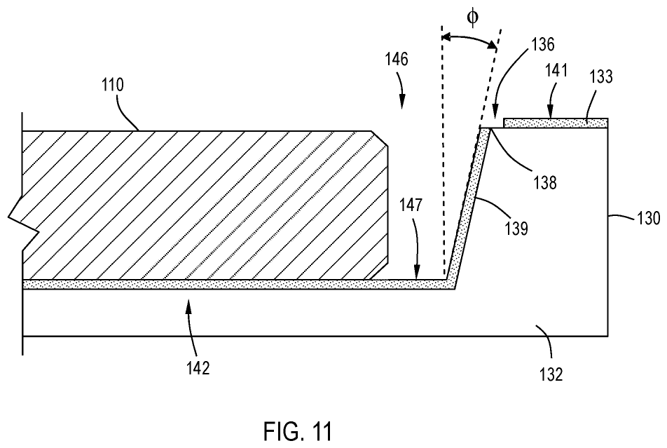

FIG. 11 shows a portion of a pocket 142 with a wafer 110 positioned therein. In the embodiment shown in FIG. 11, the pocket 142 has a slightly wider pocket diameter than the diameter of the wafer 110 to reduce wafer edge temperature around the perimeter of wafer. In the embodiment shown, the top of the pocket has a diameter about 1 mm greater than the bottom of the pocket resulting in an angle θ of about 15°. In some embodiments, the angle formed by the difference in diameter of the top of the pocket and the bottom of the pocket is in the range of about 5° to about 30°, or in the range of about 10° to about 20°.

The susceptor 130 illustrated in FIG. 11 has a susceptor body 132 with a coating 133 formed thereon. In some embodiments, the susceptor body 132 comprises graphite. In some embodiments, the coating 133 on the susceptor body 132 comprises silicon carbide. The susceptor 130 illustrated has a defect 136 at the corner 138 between coating 133 at the sidewall 139 and the top surface 141. Susceptor 130 defects include, but are not limited to chipping, peeling, cracking, etc., that expose the susceptor body 132 through the coating 133. In some embodiments, the defects occur at or near the corner 138 of the pocket 142.

However, it has been surprisingly found that incorporating an edge radius and an edge angle into the pocket 142 substantially reduces the likelihood of chipping, or forming a defect 136 in the coating 133 on the susceptor body 132. The inventors have surprisingly found that the increased corner radius and decreased angle results in a reduction in the stress on the edge of the pocket 142 compared to a pocket 142 with a sharp corner 138. The stress on the edge of the pocket 142 results in formation of the defects 136 in the coating 133 on the susceptor body 132. The defect 136 can be, for example, a chip in the coating 133, peeling of the coating 133 or a crack in the coating 133. The defect 136 can be any surface artifact that results in the exposure or potential exposure of the susceptor base 132 through the coating 133.

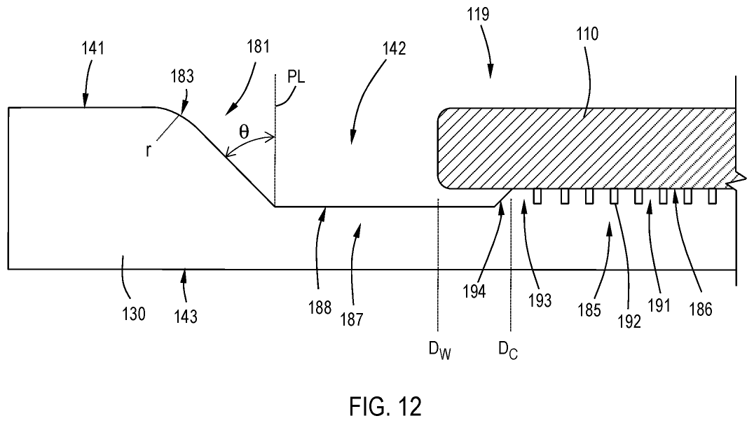

FIG. 12 shows a partial cross-sectional view of a susceptor 130 with pocket 142 formed in a surface thereof according to an embodiment of the disclosure in which the edge 181 of the pocket 142 in the susceptor 130 includes an angle θ and an edge radius 183. The susceptor 130 of some embodiments is part of a susceptor assembly 140 and includes a support post 160 (see FIG. 1) extending from a bottom surface 143 of the susceptor 130.

The illustrated pocket 142 includes a raised central region 185 upon which the wafer 110 sits. The outer portion 187 of the pocket 142 is deeper than the raised central region 185 so that the outer peripheral edge 119 of the wafer 110 is elevated above the surface 188 of the outer portion 187 of the pocket 142.

The raised central region 185 can be a continuous surface of material or can include a plurality of raised mesas 191, as shown in FIG. 7. The raised mesas 191 form a network of gas channels 192 between the mesas 191, allowing a flow of backside gas to be used. In some embodiments, there are at least some gas channels 192 in the raised central region 185 to provide a purge gas or other backside gas to flow from the center portion of the wafer 110 (or the center of the raised central region 185) to the outer portion 187 of the pocket 142. The backside gas of some embodiments helps to prevent deposition on the back side of the wafer 110. In some embodiments, the outer edge of the raised central region 185 is a seal band 193 that includes one or more openings aligned with the network of gas channels 192 to allow the gas to flow from the center of the raised central region 185 to the outer portion 187 of the pocket 142.

The diameter D_{W} of the substrate is greater than the diameter D_{C} of the raised central region 185, or the outermost ring of mesas supporting the wafer 110. In some embodiments, the difference between the diameter D_{W} of the wafer 110 and the diameter D_{C} of the raised central region 185 is in the range of 0.5 mm to 5 mm, or in the range of 1 mm to 3 mm.

The wall 194 transitioning between the raised central region 185 and the outer portion 187 is illustrated sloping downward to the surface 188 of the outer portion 187 and outward to the outer peripheral edge of the pocket 142. In some embodiments, the wall 194 is perpendicular to the wafer placement surface 186 connecting the wafer placement surface 186 with the surface 188 of the outer portion 187 with 90° angles. In some embodiments, the wall 194 has a smooth transition between the wafer placement surface 186 and the surface 188 with a curved shape (e.g., an ogee).

In some embodiments, the edge radius 183 has a radius r in the range of 0.40 mm±0.05 mm to 1.20 mm±0.05 mm. In some embodiments, the edge radius 183 is in the range of 0.50±0.05 mm to 1.00±0.05 mm.

According to one or more embodiments of the disclosure, the pocket edge angle θ is in the range of 30 to 75°. The pocket edge angle θ is measured relative to an imaginary line perpendicular PL to the surface of the outer portion 187 of the pocket 142, as shown. A pocket edge angle θ of 0° would be perpendicular to the surface 188 of the outer portion 187 of the pocket 142. In some embodiments, the pocket edge angle θ is about 30°. In some embodiments, the pocket edge angle θ is about 45°. In some embodiments, the pocket edge angle θ is about 75°.

The raised central region 185, also referred to as the wafer placement surface 186, of some embodiments is in the range of 0.1 to 0.4 mm higher than the surface 188 of the outer portion 187 of the pocket 142. In some embodiments, the outer portion 187 of the pocket 142 is in the range of 0.9 mm to 1.1 mm lower than the top surface 141 of the susceptor 130. In some embodiments, the surface 188 of the outer portion 187 of the pocket 142 is 1 mm lower than the top surface 141 of the susceptor base 148.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A susceptor assembly comprising:
a susceptor base having a plurality of pockets formed in a surface thereof, each of the pockets having a pocket edge angle in the range of 30 to 75° and a pocket edge radius in the range of 0.40 mm±0.05 mm to 1.20 mm±0.05 mm.

2. The susceptor assembly of claim 1, wherein the pockets include a raised central region defining a wafer placement surface and an outer portion that is deeper than the raised central region.

3. The susceptor assembly of claim 2, wherein the raised central region has a diameter such that an outer edge of a substrate is elevated above the outer portion of the pocket.

4. The susceptor assembly of claim 3, wherein the diameter of the raised central region is in the range of 0.5 mm to 5 mm greater than a diameter of the substrate.

5. The susceptor assembly of claim 4, wherein the diameter of the raised central region is in the range of 1 mm to 3 mm greater than the diameter of the substrate.

6. The susceptor assembly of claim 2, wherein the wafer placement surface is in the range of 0.1 mm to 0.4 mm higher than a surface of the outer portion of the pocket.

7. The susceptor assembly of claim 2, wherein the surface of the outer portion of the pocket is about 1 mm lower than the surface of the susceptor base.

8. The susceptor assembly of claim 2, wherein the raised central region is a continuous surface.

9. The susceptor assembly of claim 2, wherein the raised central region comprises a plurality of raised mesas with gas channels allowing a flow of backside gas to flow from a center portion of the raised central region to the outer portion of the pocket.

10. The susceptor assembly of claim 1, wherein the pocket edge radius is in the range of 0.50±0.05 mm to 1.00±0.05 mm.

11. The susceptor assembly of claim 1, wherein the pocket edge angle θ is 30°.

12. The susceptor assembly of claim 1, wherein the pocket edge angle θ is 45°.

13. The susceptor assembly of claim 1, wherein the pocket edge angle θ is 75°.

14. A susceptor assembly comprising:
a susceptor base having a plurality of pockets formed in a surface thereof, each of the pockets comprising a raised central region defining a wafer placement surface and an outer portion that is deeper than the raised central region, relative to the surface of the susceptor base, the wafer placement surface is in the range of 0.1 mm to 0.4 mm higher than a surface of the outer portion of the pocket, each of the pockets having a pocket edge angle in the range of 30 to 75° and a pocket edge radius in the range of 0.40±0.05 mm to 1.20 mm±0.05 mm.

15. The susceptor assembly of claim 14, wherein a diameter of the raised central region is in the range of 0.5 mm to 5 mm greater than a diameter of a substrate to be positioned on the wafer placement surface.

16. The susceptor assembly of claim 14, wherein the raised central region comprises a plurality of raised mesas with gas channels allowing a flow of backside gas to flow from a center portion of the raised central region to the outer portion of the pockets.

17. The susceptor assembly of claim 14, wherein the edge radius is in the range of 0.50±0.05 mm to 1.00±0.05 mm.

18. The susceptor assembly of claim 14, wherein the pocket edge angle θ is 30°.

19. The susceptor assembly of claim 14, wherein the pocket edge angle θ is 75°.

20. A susceptor assembly comprising:
a susceptor base having a plurality of pockets formed in a surface thereof, each of the pockets comprising a raised central region defining a wafer placement surface and an outer portion that is deeper than the raised central region, relative to the surface of the susceptor base, the raised central region having a plurality of raised mesas with gas channels allowing a flow of backside gas from a center portion of the raised central region to the outer portion of the pocket, the wafer placement surface is in the range of 0.1 mm to 0.4 mm higher than a surface of the outer portion of the pocket, each of the pockets having a pocket edge angle in the range of 30 to 75° and a pocket edge radius in the range of 0.40±0.05 mm to 1.20 mm±0.05 mm.
